(19) United States
(12) Patent Application Publication
(10) Pub. No.: US 2011/0205099 A1
(43) Pub. Date: Aug. 25, 2011

(54) SUCCESSIVE APPROXIMATION TYPE A/D CONVERTER CIRCUIT

(76) Inventor: Fumihiro Inoue, Tokyo (JP)

(21) Appl. No.: 13/126,863

(22) PCT Filed: Sep. 2, 2009
(86) PCT No.: PCT/JP2009/065331

§ 371 Date: Apr. 29, 2011

(30) Foreign Application Priority Data
Oct. 30, 2008 (JP) 2008-279340

(51) Int. Cl. H03M 1/34

(52) U.S. Cl. 341/158

(57) ABSTRACT

A successive approximation type A/D converter circuit includes a comparator circuit which determines which of an input analog voltage and a comparison voltage is larger, a register which successively takes in and stores a comparison result, and a local DA converter circuit which converts a register value into a voltage to generate the comparison voltage. The comparator circuit includes amplifier stages and a feedback capacitor connected to an input terminal of one of the amplifier stages, takes in an analog voltage during a first period, receives a input voltage depending on a potential difference between the analog and comparison voltages and amplifies the input voltage in the amplifier stage during a second period, and applies positive feedback to an input terminal of a corresponding amplifier stage via the feedback capacitor so as to impart a hysteresis of 1 LSB or less when an output of the comparator circuit changes.

### TECHNICAL FIELD

The invention relates to a technique for imparting hysteresis characteristics to a comparator in a successive approximation type AD converter circuit, and particularly relates to a technique suitably applied to an A/D converter circuit equipped with a chopper type comparator.

### BACKGROUND ART

A portable electronic device, such as a cellular phone, PDAs (Personal Digital Assistants), or a digital camera, is provided with a microprocessor for controlling the system on the inside of the device, and the microprocessor monitors the temperature, the voltage of the battery, and the like, to perform the control thereof. For the purpose of the monitoring, there is often the case where devices provided with sensors for detecting the temperature, the voltage of the battery, and the like, and a microprocessor incorporating therein an A/D converter circuit for converting analog signals from such sensors into digital signals are used.

Moreover, an A/D converter circuit is desired to take a smaller circuit size as the one to be incorporated in the microprocessor, and the like. As such an A/D converter circuit, for example, an A/D converter circuit which employs the so-called chopper type comparator using CMOS inverters as amplifiers, as shown in FIG. 9, has been known.

There has hitherto been a comparator imparted with hysteresis characteristics for prevention of an erroneous operation due to noise carried on an input signal. However, imparting the hysteresis characteristics to the comparator causes occurrence of an AD conversion error in the A/D converter circuit, and especially in an A/D converter circuit with a large number of input bits, namely with high resolution, an LSB (Least Significant Bit) as a minimum resolution is buried in a hysteresis, whereby the hysteresis characteristics have been typically not imparted.

Meanwhile, in the chopper type comparator, a potential difference between an input analog signal Vin and a comparison voltage Vref is amplified by the CMOS inverter. Thus, when Vin becomes almost an equal level to Vref, an unstable operation occurs in which an output switches between high and low due to slight fluctuations in input potential. At this switching, a current change occurs in the CMOS inverter and a power supply noise is thus generated to fluctuate a reference voltage of the comparator, thereby causing a problem of deterioration in conversion accuracy. Therefore, there has been proposed an A/D converter circuit formed so as to impart hysteresis characteristics to the chopper type comparator in order to prevent the unstable operation of the output being switched between high and low (Patent Document 1).

### PRIOR ART DOCUMENT

### Patent Document

### Patent Document 1: Japanese Patent Application Laid-Open Publication No. 6-069799

### DISCLOSURE OF THE INVENTION

### Problem to be Solved by the Invention

The invention of the prior application described in Patent Document 1 is effective in an A/D converter circuit with not very high resolution. However, the invention of the prior application has a configuration to shift a logic threshold of an inverter constituting a comparator by on-off with a feedback signal from an output in parallel with an N-MOSFET (insulating gate type field-effect transistor, hereinafter referred to as a MOS transistor) of the inverter, to impart hysteresis characteristics. According to a study conducted by the present inventors, a comparator with such a configuration has a hysteresis of several mV in the case of a source voltage of 3 to 5 V.

Therefore, in the case of an A/D converter circuit with 10 bits for example, a LSB as a minimum resolution is buried in the hysteresis to cause an increased conversion error. Further, there has been found a problem in that, since three MOS transistors are vertically laminated between a source voltage terminal and a ground point, the circuit cannot be operated with a source voltage as low as 2 V.

An object of the present invention is to provide an A/D converter circuit provided with a chopper type comparator, capable of imparting hysteresis characteristics to the comparator only by addition of a small number of elements, so as to reduce a conversion error due to noise.

Another object of the present invention is to provide an A/D converter circuit equipped with a chopper type comparator, capable of suppressing an increase in conversion error associated with imparting of the hysteresis, by imparting hysteresis characteristics of 1 LSB or less to the comparator.

### Means for Solving Problems

In order to achieve the above objects, the present invention provides a successive approximation type A/D converter circuit, including: a comparator circuit which determines which of an input analog voltage and a comparison voltage is larger; a register which successively takes in and stores a determination result of the comparator circuit; and a local DA converter circuit which converts a value of the register into a voltage to generate the comparison voltage, wherein the comparator circuit includes one or more amplifier stages and a feedback capacitor which is connected to an input terminal of any one of the amplifier stages, takes in an analog voltage during a first period, receives a input voltage depending on a potential difference between the input analog voltage and the comparison voltage and amplifies the input voltage in the amplifier stage during a second period, and applies positive feedback to an input terminal of a corresponding amplifier stage via the feedback capacitor so as to impart a hysteresis of 1 LSB or less when an output of the comparator circuit changes.

According to the above configuration, since it is a configuration where positive feedback is applied to the input terminal of any one of the amplifier stages via the feedback capacitor, a small hysteresis can be imparted and only a small number of elements are to be added as compared with the case of adding hysteresis characteristics to the amplifier stage itself.

Herein, the capacitance value of the feedback capacitor is desirably determined such that the hysteresis has a size of one-half of 1 LSB or less. The capacitance value of the feedback capacitor is more desirably determined such that the hysteresis has a size of one-fifth of 1 LSB or less. The capacitance value of the feedback capacitor is further desirably determined such that the hysteresis has a size of one-tenth of 1 LSB or less. It is thereby possible to reduce noise which occurs due to switching of the output of the comparator circuit without increasing a conversion error.

Further, it is desirable that the comparator circuit has two or more amplifier stages connected in cascade, and the amplifier stage whose corresponding input terminal is applied with positive feedback via the feedback capacitor is a last amplifier stage. Forming a configuration where positive feedback is applied to the last amplifier stages can make a hysteresis small at the time of conversion into an input, so as to facilitate imparting of a hysteresis of 1 LSB or less.

Further, the comparator circuit desirably includes one or more CMOS inverters as the amplifier stages, and further includes a switch element provided between an input terminal and an output terminal of each of the CMOS inverters and a capacitance provided between the CMOS inverters, during the first period, the switch element is turned into an on-state, a voltage corresponding to a logic threshold of the CMOS inverter is applied to one terminal of a sampling capacitor, and the comparator circuit takes in an input analog voltage with the applied voltage used as a reference, during the second period, an electric charge depending on a potential difference between the input analog voltage and the comparison voltage is charged in the sampling capacitor, and the switch element is brought into an off-state to amplify a potential of the sampling capacitor by the CMOS inverter, and when an output of the comparator circuit changes, positive feedback is applied to an input terminal of a corresponding CMOS inverter via the feedback capacitor. It is thereby possible to reduce the number of components of the comparator, so as to reduce an occupied area of the circuit.

Further, a subsequent stage to the comparator circuit is desirably provided with a logic gate which receives an output of the last amplifier stage of the comparator circuit and a clock signal which gives timing for the sampling, a potential of one terminal of the feedback capacitor is changed by the output of the logic gate or a signal inverted thereto, and positive feedback is applied to the input terminal of the corresponding CMOS inverter. It is thereby possible to prevent an intermediate potential of the inverter as the amplifier stage from being transmitted to a subsequent circuit (successive approximation register, etc) during sampling.

### EFFECTS OF THE INVENTION

According to the present invention, in the A/D converter circuit equipped with the chopper type comparator, it is possible to impart hysteresis characteristics to the comparator only by addition of a small number of elements, so as to reduce a conversion error due to noise. Further, it is possible to impart hysteresis characteristics of 1 LSB or less to the comparator, so as to suppress an increase in conversion error associated with imparting of the hysteresis.

### BRIEF DESCRIPTION OF THE DRAWINGS

FIG. 1 is a circuit constitutional diagram showing an embodiment of a successive approximation type A/D converter circuit according to the present invention;

FIG. 2 is a state explanatory diagram showing a state of a node potential state inside a comparator of the A/D converter circuit of the embodiment;

FIG. 3 is a circuit constitutional diagram showing a constitutional example of a comparator in a first modification of the A/D converter circuit of the embodiment;

FIG. 4 is a circuit constitutional diagram showing a constitutional example of a comparator in a second modification of the A/D converter circuit of the embodiment;

FIG. 5 is a circuit constitutional diagram showing a constitutional example of a comparator in a third modification of the A/D converter circuit of the embodiment;

FIG. 6 is a circuit constitutional diagram showing a constitutional example of a comparator in a fourth modification of the A/D converter circuit of the embodiment;

FIG. 7 is a circuit constitutional diagram showing a second embodiment of the successive approximation type A/D converter circuit according to the present invention;

FIG. 8 is a circuit constitutional diagram showing a state of each of change-over switches SW0 to SWn−1 in a comparison determination period (hold period) of the successive approximation type A/D converter circuit of a second embodiment; and

FIG. 9 is a circuit constitutional diagram showing a constitutional example of a conventional AD conversion circuit equipped with a chopper type comparator.

### BEST MODE FOR CARRYING OUT THE INVENTION

Hereinafter, preferred embodiments of the present invention are described based on drawings.

FIG. 1 shows an embodiment of a successive approximation type A/D converter circuit according to the present invention. The A/D converter circuit shown in FIG. 1 includes: a sample/hold circuit S&H which alternately samples an analog input Vin input to an analog input terminal IN and a comparison voltage Vref applied to a reference voltage terminal to hold a difference voltage; a chopper type comparator CMP which amplifies the difference voltage sampled by the sample/hold circuit S&H; a logic circuit LG which receives an output of the chopper type comparator CMP and a sampling clock φs and outputs a predetermined signal; a successive approximation register SAR which successively takes in outputs of the logic circuit LG; and a local DA converter circuit DAC which outputs to the sample/hold circuit S&H, as the comparison voltage Vref, a voltage obtained by DA conversion of an output code of the register SAR by switching of an internal switch by means of a signal output from the SAR.

The sample/hold circuit S&H includes a pair of sampling switches SS1, SS2 which are complementarily turned on and off by a sampling clock φs and a clock/φs of an opposite phase thereto, and a sampling capacitor Cs connected between a connection node of the switches SS1, SS2 and an input terminal of the chopper type comparator CMP. The logic circuit LG includes a NOR gate G1 which receives the output of the chopper type comparator CMP and the sampling clock φs and outputs a signal obtained by taking AND of those signals, and an inverter G2 which inverts the output of the NOR gate G1.

Further, the chopper type comparator CMP has a configuration in which three CMOS inverters INV1, INV2, INV3 are connected in cascade via capacitors C1, C2, and switches S1, S2, S3 which short-circuits input/output terminals of the inverters respectively are provided. A feedback capacitor Cf is connected between an output terminal of the NOR gate G1 and an input terminal of the inverter INV3 in a last stage. The NOR gate G1 is provided for the purpose of preventing an output of the inverter INV3 from being transmitted to a subsequent circuit (successive approximation register, etc.), the output becoming a potential in the middle of a high level and a low level by turning on the switch S3 during sampling.

In the comparator CMP of the embodiment, during a sampling period, the switches S1, S2, S3 are turned on to short-circuit the inputs/outputs of the inverters INV1, INV2, INV3, and thereby an input potential and an output potential of each of the inverters become potentials equal to a logic threshold VLT thereof. For this reason, in the sample/hold circuit S&H, the switch SS1 on the input terminal side is turned to an on-state by the sampling clock φs. Thereby, the input analog voltage Vin is sampled in the sampling capacitor Cs with VLT used as a reference. That is, Cs is charged with an electric charge depending on a potential difference between VLT and Vin. Further, the capacitors C1, C2 are charged with voltages (VLT2−VLT1), (VLT3−VLT2) corresponding to differences between the logic thresholds of the respective inverters.

During comparison determination (hold period), in the sample/hold circuit S&H, the switch SS2 on the reference side is turned into an on-state by the sampling clock/Os. Thereby, an electric charge corresponding to a potential difference (Vref−Vin) between the input analog voltage Vin and the comparison voltage Vref remains in the sampling capacitor Cs. Further, in the comparator CMP, the switches S1, S2, S3 are turned off by φs for interruption between the inputs/outputs of the inverters INV1, INV2, INV3, whereby each of the inverters operates as an amplifies and the output thereof changes according to an input potential.

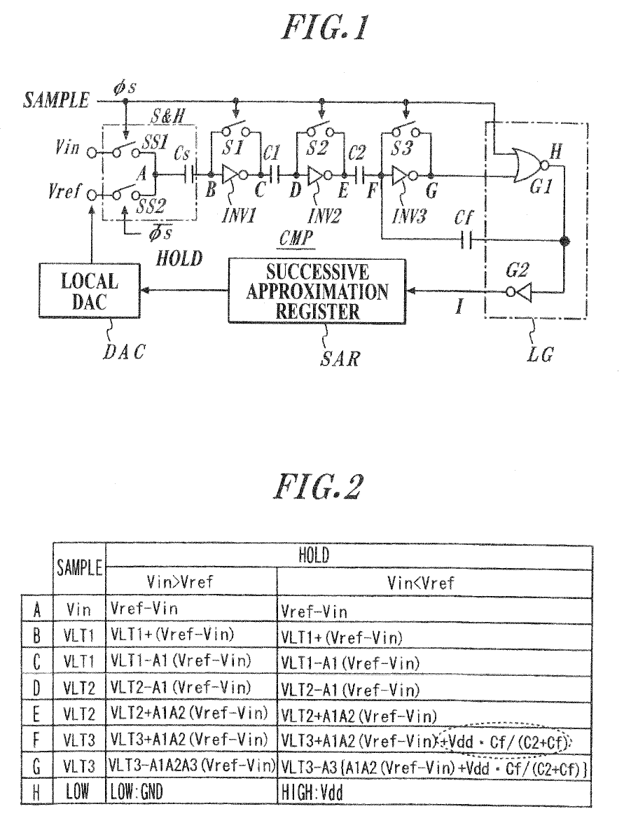

At this time, the potential difference (Vref−Vin) is transmitted to an input terminal of the inverter INV1 in a first stage via the sampling capacitor Cs, and the potential difference is gradually amplified by the inverters INV1, INV2, INV3. As a consequence, a result of comparison between the input analog voltage Vin and the comparison voltage Vref appears in the output of the inverter INV3. Specifically, assuming that the logic thresholds of the inverters INV1, INV2, INV3 are VLT1, VLT2, VLT3, gains (amplification factors) are A1, A2, A3, and a source voltage is Vdd, potentials A to H of the respective nodes in the circuit of FIG. 1 are as shown in FIG. 2. It is found from FIG. 2 that the output of the inverter INV3 becomes a low level (ground potential GND) when Vin is higher than Vref, and the output of the inverter INV3 becomes a high level (power voltage Vdd) when Vin is lower than Vref.

In this embodiment, since the feedback capacitor Cf is connected between the output terminal of the NOR gate G1 and the input terminal of the inverter INV3 in the last stage, when the output potential of the NOR gate G1 becomes high, an electric charge of the feedback capacitor Cf is distributed between Cf and C2 according to a capacitance ratio so as to apply positive feedback to the input terminal of the inverter INV3, and the input potential thus becomes higher just by ΔV than an input potential of a circuit not provided with the capacitor Cf. Herein, since the electric charge before the distribution is equal to the electric charge after the distribution, Q=Cf·Vdd=(C2+Cf)·ΔV is held. Thereby, ΔV=Vdd·Cf/(C2+Cf) is obtained, and the input potential F becomes VLT3+A1·A2·(Vref−Vin)+Vdd·Cf/(C2+Cf) (refer to within the enclosure of the dotted line of FIG. 2).

Further, the positive feedback amount ΔV in the input node of the inverter INV3 can be divided by gains A1, A2 of the inverters INV1, INV2 which operate as the amplifier stages, so as to be converted into inputs. Thereby, a hysteresis amount Vhys in the input node of the inverter INV1 can be expressed by the following equation:

Vhys=Vdd·Cf/(C2+Cf)·A1·A2 (1)

Accordingly, in the case of imparting a hysteresis on the order of 0.1 LSB (=Vdd/10·2¹⁰) in a 10-bit A/D converter circuit for example, when the respective gains of the inverters INV1, INV2 are 50 times, Vhys=Vdd·Cf (C2+Cf)·50·50=Vdd/10·2¹⁰ Thereby, Cf/(C2+Cf)≅¼, and it is found that C2:Cf≅ the order of 3:1 may be set.

As described above, by applying the present embodiment, a small hysteresis on the order of 1 LSB can be imparted to the chopper type comparator CMP by simple design change of adding only one capacitor. Herein, when the hysteresis of the chopper type comparator used in the A/D converter circuit is smaller than the LSB and larger than thermal noise, it can prevent switching of the output of the comparator due to thermal noise so as to make conversion accuracy high.

Further, in FIG. 1, a configuration where capacitors are added to between the inputs/outputs of the respective inverters INV1, INV2 so as to adjust the gains of the inverter INV1, INV2 may be adopted. In this case, a ratio between C2 and Cf can be set based on a result of calculation made by adjusted predetermined gains. Although the capacitor may be added to either the inverter INV1 or the inverter INV2, or may be added to both of the inverters, a larger effect is exerted on noise reduction in the chopper type comparator CMP in the case of adding the capacitor to INV1.

In the configuration as described in Patent Document 1), since a hysteresis of 1 LSB or less is difficult to be imparted in the 10-bit A/D converter circuit, when imparting a hysteresis for preventing switching of the output of the comparator due to thermal noise, a quantization error increases. However, when the present embodiment is applied, it is possible to prevent switching of the output of the comparator due to thermal noise without increasing a quantization error difference, so as to enhance the conversion accuracy.

However, the hysteresis also becomes a conversion error, although a small one. Hence in the A/D converter circuit for use in a system with a large fluctuation in source voltage, such as a system which operates by a battery, it is desirable to prevent an erroneous operation due to noise by decreasing the hysteresis to reduce an error when the source voltage Vdd is low, and increasing the hysteresis in a state where the source voltage Vdd is high to cause an increase in noise level. From such a viewpoint, the comparator of the abovementioned embodiment will be examined.

When a transfer conductance of the MOS transistor is referred to as gm, a threshold voltage as Vth, an output resistance as r0, an early voltage as VA, a gate-source voltage as Vgs, a drain-source voltage as Vds, and a drain current as Ids,

r0=(VA+Vds)/Ids

gm=2Ids/(Vgs−Vth)

Thereby, the gain G (=gm·r0) of the MOS transistor is expressed by:

G=2Ids·(VA+Vds)/(Vgs−Vth)·Ids=2(VA+Vds)/(Vgs−Vth) (2)

In this equation, the denominator (Vgs−Vth) is an effective voltage to be applied to the gate of the MOS transistor, and this effective voltage becomes larger with a higher source voltage Vdd, and becomes smaller with a lower Vdd. Therefore, it is found from the above equation (2) that the gain becomes larger as the source voltage Vdd becomes higher and the effective voltage becomes larger, and the gain becomes smaller as the source voltage Vdd becomes lower and the effective voltage becomes smaller.

On the other hand, in the foregoing comparator of the embodiment, from the equation (1), the hysteresis becomes larger as the voltage Vdd is higher and the gain of the inverter is larger, and the hysteresis becomes smaller as the voltage Vdd is lower and the gain of the inverter is smaller. Further, the gain of the inverter becomes larger as the gain of the MOS transistor is larger. Therefore, it can be said that the comparator of the embodiment, in which hysteresis becomes larger as the source voltage is higher according to fluctuations in source voltage, is suitable for the A/D converter circuit for use in a system with large fluctuations in source voltage.

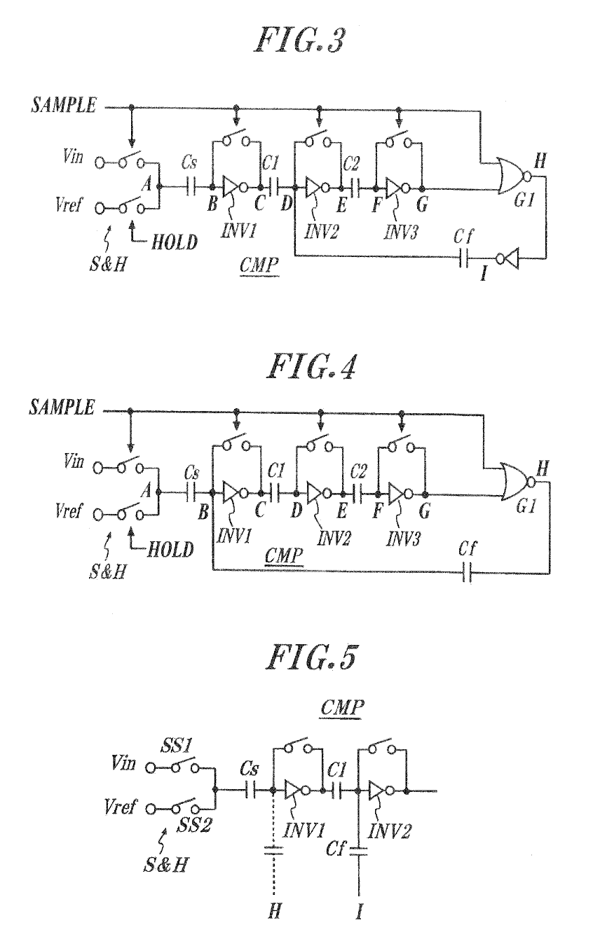

FIGS. 3 to 6 show modifications of the comparator of the embodiment. Among them, FIG. 3 is an example where a position to which positive feedback is applied from the output side is set to an input node of the second-stage inverter INV2, and FIG. 4 is an example where a position to which positive feedback is applied from the output side is set to an input node of the first-stage inverter INV1. Even when the position to which positive feedback is applied is changed as above, almost the same effect as the embodiment of FIG. 1 can be obtained.

In this regard, however, in the case of imparting the same hysteresis in terms of an input, it is necessary to make the feedback capacitor Cf of FIG. 3 smaller than that of FIG. 1, and make the feedback capacitor Cf of FIG. 4 further smaller than that of FIG. 3. Moreover, in FIG. 3, feedback is applied by the signal I of the opposite phase to in FIG. 1, and in FIG. 4, feedback is applied by the signal H of the same phase as in FIG. 1.

FIG. 5 is a configuration formed such that positive feedback is applied to an input terminal of the inverter INV2 in the second stage from the output side when the comparator CMP includes two stages of the inverters INV1, INV2. As indicated by dashed lines in FIG. 5, a configuration may be formed such that positive feedback is applied to the input terminal of the first-stage inverter INV1. It is to be noted that, when there are three stages of inverters and positive feedback is to be applied to the input terminal of the first-stage inverter INV1, it is necessary to make the capacitance value of Cf smaller (e.g. 1/1000) than in the case of positive feedback being applied to the third-stage inverter as in FIG. 1. In that case, although it is also expected that Cf cannot be composed of an element having the identical structure to C2, such small Cf can be configured through use of an inter-wire capacitance and the like.

FIG. 6 shows a manner to apply feedback in the case of the comparator CMP including three differential amplifier stages. In FIG. 6, H indicates that feedback is applied by a signal of the same phase as the output of the NOR gate G1 in FIG. 1, and I indicates that feedback is applied by a signal of the opposite phase to the output of the NOR gate G1 in FIG. 1. It is to be noted that, though FIG. 6 shows a state where positive feedbacks are applied to both of the differential signals, positive feedback may be applied to either one of the differential signals.

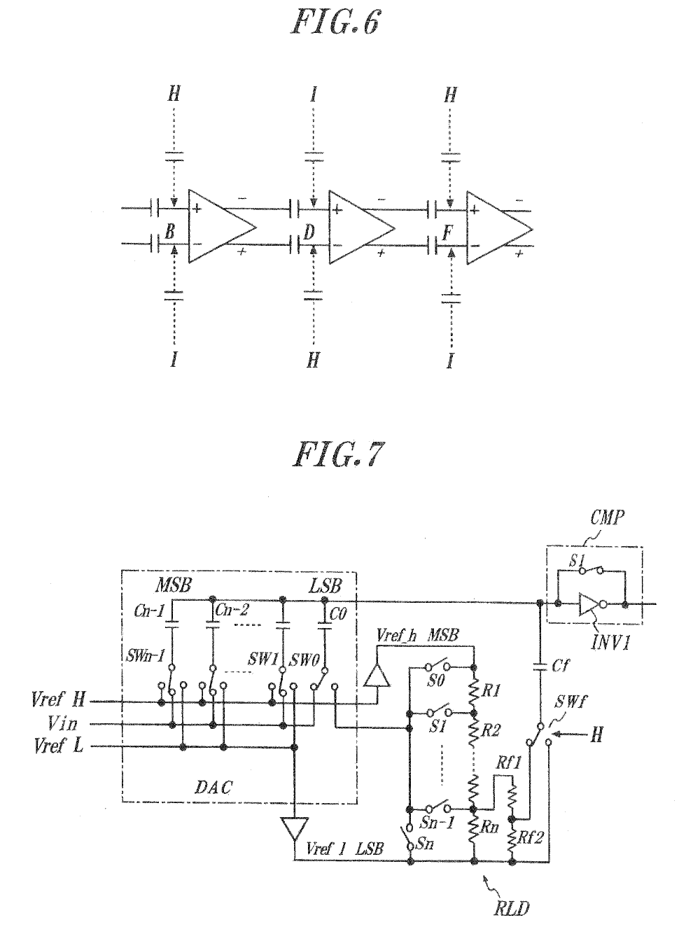

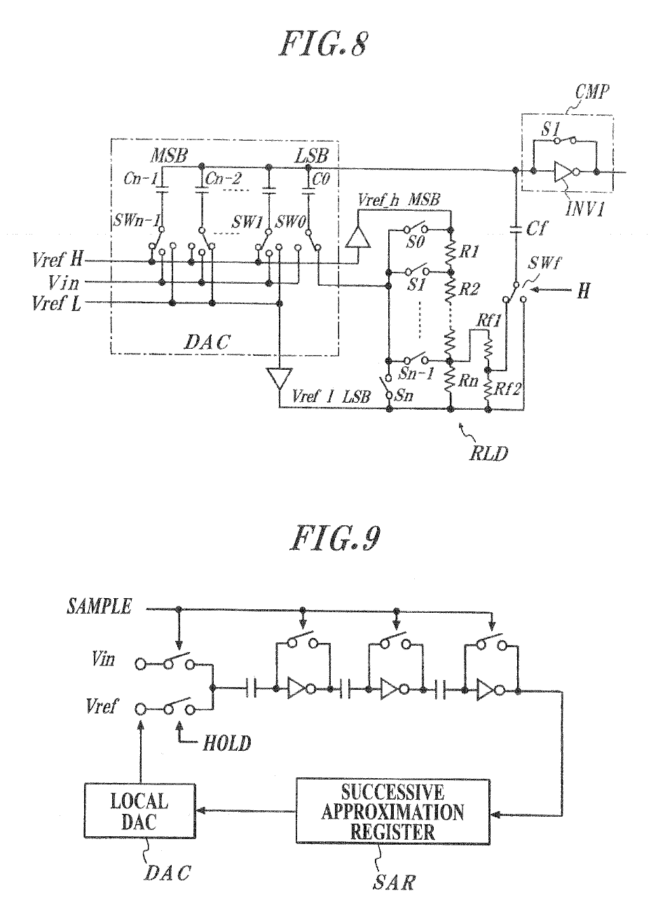

FIG. 7 shows a second embodiment of a successive approximation type A/D converter circuit according to the present invention. In this embodiment, a DA converter circuit in combination of a charge distribution type and a resistance voltage divider type is used as the local DA converter circuit, and positive feedback is applied to the input terminal of the first-stage inverter INV1. This embodiment can be said to be a specific example of the modification of FIG. 4. Further, the local DA converter circuit in the present embodiment corresponds to a circuit having both performances of the sample/hold circuit S&H and the local DA converter circuit DAC in the embodiment of FIG. 1.

The local DA converter circuit DAC in this embodiment has a capacitor array including weight capacitors C0, C1, . . . , Cn−1 with a weight of the nth power of 2, and a ladder resistor RLD including serially formed resistors R1 to Rn. The resistors R1 to Rn are normally set to the same resistance value. One terminals of the weight capacitors C0, C1, . . . , Cn−1 are commonly connected, to be connected to the input terminal of the first-stage inverter INV1 of the comparator CMP.

To the other terminals of weight capacitors C1, . . . , Cn−1 among C0, C1, . . . , Cn−1, either reference voltages Vref_h, Vref_l or the input voltage Vin is made applicable by changeover switches SW1 to SWn−1. Further, to the other terminal of the weight capacitor C0, either a selection voltage of the ladder resistor RLD or the input voltage Vin is made applicable by a changeover switch SWO. It should be noted a combined total of the weight capacitors C0, C1, . . . , Cn−1 corresponds to the sampling capacitor Cs in FIG. 4. For the reference voltage Vref_l, a ground potential may be used. Making Vref_l a higher potential than the ground potential allows a change in AD-convertible voltage range FSR (Full Scale Range).

The ladder resistor RLD is provided with switches S0, S1, . . . , Sn which take out potentials of the respective nodes of the ladder resistor. In this embodiment, the changeover switches SW0 to SWn−1 are controlled by higher-order bits of the successive approximation register SAR, and the switches S0 to Sn are controlled by lower-order bits of the register SAR. Specifically, when the potential of the ladder resistor RLD is used by the lower-order bits of SAR, any one of the switches S0 to Sn−1 is turned on, only SW0 operates among the changeover switches SW0 to SWn−1, and SW1 to SWn−1 do not operate.

When the weight capacitors C0, C1, . . . , Cn−1 are used, the switch S0 or Sn is turned into an on-state, and S1 to Sn or S0 to Sn−1 are brought into an off-state, whereby the reference voltage Vref_h or Vref_l is transmitted to the capacitor C0 via the changeover switch SW0. SW1 to SWn−1 are connected to the input terminal of Vin during sampling, and connected to the reference voltage Vref_h or Vref_l according to the higher-order bits of the register SAR during comparison determination.

Connection terminals of the changeover switches SW0 to SWn−1 are determined according to a value of the successive approximation register SAR and a sampling clock. FIG. 7 shows a state of each of the switches during the sampling period. The changeover switches SW0 to SWn−1 apply the input voltage Vin to the other terminals of the corresponding weight capacitors C0, C1, . . . , Cn−1, and are charged with electric charges according to potentials of the input voltage.

FIG. 8 shows a state of each of the changeover switches SW0 to SWn−1 during the comparison determination period (hold period). As shown in FIG. 8, the changeover switches SW0 to SWn−1 during the comparison determination period are either Vref_h or Vref_l. Further, the changeover switch SW0 is a selection voltage of the ladder resistor RLD, and which node of the voltage is selected is determined by the switches S1 to Sn. During the comparison determination period, by applying either the reference voltage Vref_h or Vref_l to the other terminals of the weight capacitors C0, C1, . . . , Cn−1, an electric charge depending on a potential difference between the applied voltage and the input Vin applied immediately before remains, which is then distributed among C0, C1, . . . , Cn−1, and a voltage generated in the common connection node is supplied to the input terminal of the inverter INV1 as the comparator.

In the comparator, during the sampling period, the Switch S1 is turned on and the input and output of the inverter INV1 are short-circuited, thereby the input potential and the output potential become potentials equal to the logic threshold VLT of the inverter. The input analog voltage Vin is sampled in each of the weight capacitors C0, C1, . . . , Cn−1 with VLT used as a reference. That is, an electric charge depending on a potential difference between VLT and Vin is charged.

During comparison determination, as described above, the changeover switches SW0 to SWn−1 are connected to the reference voltage Vref_h or Vref_l according to the value of the register SAR in the local DAC. Thereby, the input terminal of the inverter INV1 is supplied with a potential depending on a potential difference between the input analog voltage sampled immediately before and the comparison voltage determined based on the states of the changeover switches SW0 to SWn−1. Since the switch S1 is turned off and the input terminal and the output terminal of the inverter INV are separated off, the inverter acts as an amplifier to amplify an input potential and output the amplified potential.

In a resistance voltage division DA converting section, the reference voltage Vref_h is applied to one terminal of the ladder resistor RLD, the reference voltage Vref_l is applied to the other terminal of the ladder resistor RLD, and either voltage obtained by dividing a potential difference therebetween with a resistance ratio is taken out by the switches S0 to Sn controlled by the lower-order bits of the register SAR.

As described above, by combining the charge distribution type with the resistance voltage divider type, only a capacitance 2⁵ times (32 times) as large as that of the minimal capacitor C0 and 32 resistors are required to be arranged, whereas the capacitance 2¹⁰ times (about 1000 times) as large as that of C0 has been required in the case of only the charge division system being used, which is thus advantageous in term of the area.

Moreover, in this embodiment, in order to apply feedback to one terminal of the feedback capacitor Cf, there are provided serial resistors Rf1, Rf2 in parallel with the resistor Rn, and a switch SWf which selects either a potential of a connection node of Rf1 and Rf2 or the reference voltage Vref_l so as to apply the selected one to the one terminal of the capacitor Cf. The switch SWf is controlled by the output of the NOR gate G1, and makes the potential of the connection node of the Rf1 and Rf2 applied to Cf at the time of the high level, and makes the reference voltage Vref_l applied to Cf at the time of the low level.

A synthetic resistance value of the resistors Rn, Rf1, Rf2 is set to be the same resistance value as the other resistors R0 to Rn−1, and a resistance ratio between the resistors Rf1 and Rf2 is set to be such a ratio as 9:1 according to an amount of a hysteresis to be imparted. Further, a capacitance value of Cf is made equal to the minimal capacitor C0 among the weight capacitors. This allows imparting of a hysteresis of one-tenth of 1 LSB. Moreover, making the capacitance value of Cf smaller than the minimal weight capacitor C0 allows imparting of a smaller hysteresis. It should noted that, although the resistors Rf1, Rf2 for giving a potential to be applied to the feedback capacitor Cf are provided in parallel with the resistor Rn of the ladder resistor RLD in the embodiment of FIG. 7, the resistors Rf1, Rf2 can also be provided in parallel with the resistors Rn−1 and Rn when the resistance value is appropriately set.

Although the invention made by the present inventors was specifically described based on the embodiments, the present invention is not limited to the embodiments. For example, although the comparator with three stages of CMOS inverters connected in cascade was shown in the embodiments, a comparator with two inverters connected in cascade or a comparator made up of one inverter may also be employed.

Further, although the configuration where the feedback capacitor Cf is connected between the output terminal of the NOR gate G1 in the subsequent stage to the comparator CMP and the input terminal of any one of the CMOS inverters was shown in the embodiment, the configuration may be formed such that the feedback capacitor Cf is previously connected between the input terminal of any one of the CMOS inverters and a predetermined fixed potential point with a switch element in series, and the switch element is configured to perform turning-on/off operations by the output of the NOR gate G1, to apply positive feedback. A NAND gate can also be used in place of the NOR gate.

Moreover, although the descriptions were made in the embodiments assuming the normal inverter with the P-MOS and the N-MOS connected in series as the CMOS inverter constituting the chopper type comparator, an inverter of a clocked inverter type, where on/off controlling transistors (P-MOS, N-MOS) are connected in series with P-MOS and N-MOS for amplification to be applied with an input voltage (voltage from the local DAC), may be used as the CMOS inverter constituting the comparator, to control the timing for the operation so as to seek for low power consumption.

### INDUSTRIAL APPLICABILITY

The present invention is applicable to a chopper type comparator and an A/D converter circuit equipped with the same.

### REFERENCE NUMERALS

S/H Sample/hold circuit
CMP Comparator
SAR Successive approximation register
DAC Local DA converter circuit
LG Logic circuit
S1, S2, S3 Short-circuit switch
C1, C2 Capacitor
Cf Feedback capacitor
RLD Ladder resistor
C0 to Cn−1 Weight capacitor
SW0 to SWn−1 Changeover switch

1. A successive approximation type A/D converter circuit, comprising:
a comparator circuit which determines which of an input analog voltage and a comparison voltage is larger;
a register which successively takes in and stores a determination result of the comparator circuit; and
a local DA converter circuit which converts a value of the register into a voltage to generate the comparison voltage,
wherein the comparator circuit includes one or more amplifier stages and a feedback capacitor which is connected to an input terminal of any one of the amplifier stages, takes in an analog voltage during a first period, receives a input voltage depending on a potential difference between the input analog voltage and the comparison voltage and amplifies the input voltage in the amplifier stage during a second period, and applies positive feedback to an input terminal of a corresponding amplifier stage via the feedback capacitor so as to impart a hysteresis of 1 LSB or less when an output of the comparator circuit changes.

2. The successive approximation type A/D converter circuit according to claim 1, wherein a capacitance value of the feedback capacitor is determined such that the hysteresis has a size of one-half of 1 LSB or less.

3. The successive approximation type A/D converter circuit according to claim 1, wherein:
the comparator circuit has two or more amplifier stages connected in cascade, and
the amplifier stage whose corresponding input terminal is applied with positive feedback via the feedback capacitor is a last amplifier stage.

4. The successive approximation type A/D converter circuit according to claim 1, wherein:
the comparator circuit includes one or more CMOS inverters as the amplifier stages, and further includes a switch element provided between an input terminal and an output terminal of each of the CMOS inverters and a capacitance provided between the CMOS inverters,
during the first period, the switch element is turned into an on-state, a voltage corresponding to a logic threshold of the CMOS inverter is applied to one terminal of a sampling capacitor, and the comparator circuit takes in an input analog voltage with the applied voltage used as a reference,
during the second period, an electric charge depending on a potential difference between the input analog voltage and the comparison voltage is charged in the sampling capacitor, and the switch element is brought into an off-state to amplify a potential of the sampling capacitor by the CMOS inverter, and
when an output of the comparator circuit changes, positive feedback is applied to an input terminal of a corresponding CMOS inverter via the feedback capacitor.

5. The successive approximation type A/D converter circuit according to claim 4, wherein a subsequent stage to the comparator circuit is provided with a logic gate which receives an output of the last amplifier stage of the comparator circuit and a clock signal which gives timing for the sampling, a potential of one terminal of the feedback capacitor is changed by the output of the logic gate or a signal inverted thereto, and positive feedback is applied to the input terminal of the corresponding CMOS inverter.

6. The successive approximation type A/D converter circuit according to claim 2, wherein:
the comparator circuit has two or more amplifier stages connected in cascade, and
the amplifier stage whose corresponding input terminal is applied with positive feedback via the feedback capacitor is a last amplifier stage.

7. The successive approximation type A/D converter circuit according to claim 2, wherein:
the comparator circuit includes one or more CMOS inverters as the amplifier stages, and further includes a switch element provided between an input terminal and an output terminal of each of the CMOS inverters and a capacitance provided between the CMOS inverters,
during the first period, the switch element is turned into an on-state, a voltage corresponding to a logic threshold of the CMOS inverter is applied to one terminal of a sampling capacitor, and the comparator circuit takes in an input analog voltage with the applied voltage used as a reference,
during the second period, an electric charge depending on a potential difference between the input analog voltage and the comparison voltage is charged in the sampling capacitor, and the switch element is brought into an off-state to amplify a potential of the sampling capacitor by the CMOS inverter, and
when an output of the comparator circuit changes, positive feedback is applied to an input terminal of a corresponding CMOS inverter via the feedback capacitor.

8. The successive approximation type A/D converter circuit according to claim 7, wherein a subsequent stage to the comparator circuit is provided with a logic gate which receives an output of the last amplifier stage of the comparator circuit and a clock signal which gives timing for the sampling, a potential of one terminal of the feedback capacitor is changed by the output of the logic gate or a signal inverted thereto, and positive feedback is applied to the input terminal of the corresponding CMOS inverter.

9. The successive approximation type A/D converter circuit according to claim 3, wherein:
the comparator circuit includes one or more CMOS inverters as the amplifier stages, and further includes a switch element provided between an input terminal and an output terminal of each of the CMOS inverters and a capacitance provided between the CMOS inverters,
during the first period, the switch element is turned into an on-state, a voltage corresponding to a logic threshold of the CMOS inverter is applied to one terminal of a sampling capacitor, and the comparator circuit takes in an input analog voltage with the applied voltage used as a reference,
during the second period, an electric charge depending on a potential difference between the input analog voltage and the comparison voltage is charged in the sampling capacitor, and the switch element is brought into an off-state to amplify a potential of the sampling capacitor by the CMOS inverter, and
when an output of the comparator circuit changes, positive feedback is applied to an input terminal of a corresponding CMOS inverter via the feedback capacitor.

10. The successive approximation type A/D converter circuit according to claim 9, wherein a subsequent stage to the comparator circuit is provided with a logic gate which receives an output of the last amplifier stage of the comparator circuit and a clock signal which gives timing for the sampling, a potential of one terminal of the feedback capacitor is changed by the output of the logic gate or a signal inverted thereto, and positive feedback is applied to the input terminal of the corresponding CMOS inverter.
